(19) United States
(12) Patent Application Publication
(10) Pub. No.: US 2008/0122119 A1
(43) Pub. Date: May 29, 2008

(54) METHOD AND APPARATUS FOR CREATING RFID DEVICES USING MASKING TECHNIQUES

(75) Inventors: Kouroche Kian, Altadena, CA (US); Xiaoming He, Arcadia, CA (US); Ali Mehrabi, Glendale, CA (US); Haochuan Wang, South Pasadena, CA (US)

Correspondence Address: JEFFER, MANGELS, BUTLER & MARMARO, LLP, 1900 AVENUE OF THE STARS, 7TH FLOOR, LOS ANGELES, CA, 90067, US

(73) Assignee: AVERY DENNISON CORPORATION, Pasadena, CA (US)

(21) Appl. No.: 11/469,313

(22) Filed: Aug. 31, 2006

(51) Int. Cl. H01L 23/12; H01L 21/58

(52) U.S. Cl. 257/783; 438/118; 257/E23.003; 257/E21.505

(57) ABSTRACT

A method for creating a plurality of semiconductor assemblies that includes the steps of creating a plurality of quasi-wafers, each quasi-wafer comprising a plurality of semiconductor devices; transferring the plurality of semiconductor devices on each quasi-wafers onto a carrier having a functional adhesive; and bonding the plurality of semiconductor devices to a substrate.

### BACKGROUND

1. Field

The present invention relates generally to manufacturing of semiconductor devices, and more particularly, to a method and apparatus for creating RFID devices using masking techniques.

2. Background

Automatic identification of products has become commonplace. For example, the ubiquitous barcode label, placed on food, clothing, and other objects, is currently the most widespread automatic identification technology that is used to provide merchants, retailers and shippers with information associated with each object or item of merchandise.

Another technology used for automatic identification products is Radio Frequency Identification (RFID). RFID uses labels or “tags” that include electronic components that respond to radio frequency commands and signals to provide identification of each tag wirelessly. Generally, RFID tags and labels comprise an integrated circuit (IC, or chip) attached to an antenna that responds to a reader using radio waves to store and access the ID information in the chip. Specifically, RFID tags and labels have a combination of antennas and analog and/or digital electronics, which often includes communications electronics, data memory, and control logic.

One of the obstacles to more widespread adoption of RFID technology is that the cost of RFID devices such as tags or labels is still relatively high as lower cost manufacturing of RFID devices has not been achievable using current production methods. Additionally, as the demand for RFID devices has increased, the pressure has increased for manufacturers to reduce the cost of the devices, as well as to reduce the size of the electronics as much as possible so as to: (1) increase the yield of the number of dies (i.e., chips) that may be produced from a semiconductor wafer, (2) reduce the potential for damage, as the final device size is smaller, and (3) increase the amount of flexibility in deployment, as the reduced amount of space needed to provide the same functionality may be used to provide more capability.

However, as the chips become smaller, the process of interconnecting them with other device components, such as antennas, becomes more difficult. Thus, to interconnect the relatively small contact pads on the chips to the antennas in RFID inlays, intermediate structures variously referred to as “strap leads,” “interposers,” and “carriers” are sometimes used to facilitate inlay manufacture. The intermediate structure include conductive leads or pads that are electrically coupled to the contact pads of the chips for coupling the chips to the antennas. These leads provide a larger effective electrical contact area between the chips and the antenna than do the contact pads of the chip alone. With the use of intermediate structure, the alignment between the chip and the antenna does not have to be as precise during the direct placement of the chip on the antenna as without the use of such intermediate structure. The larger contact area provided by the intermediate structures reduces the accuracy required for placement of the chips during manufacture while still providing effective electrical connection between the chip and the antenna. However, the accurate placement and mounting of the chips on the intermediate structures still provide serious obstacles for high-speed manufacturing of RFID tags and labels.

Some challenges that currently face manufacturers or suppliers to component manufacturers include:

1) Wafer Processing: Transfer of chips from a wafer to a suitable substrate.

2) Chip Attachment: Accurately positioning of chips for attachment to intermediate structures is difficult to achieve at the speeds needed to achieve the economies of scale obtainable through high volume manufacturing.

3) Bonding: It is difficult to accurately bond, cure, and electrically connect the chips to intermediate structures at rates necessary to achieve high volume manufacturing.

Several possible high-speed intermediate structure assembly strategies have been proposed. The first approach, which uses the “pick-and-place” machines typically deployed in the manufacturing of circuit boards for picking up electronic components and placing them on circuit boards, is accurate, but requires expensive machines that ultimately do not deliver a sufficient throughput to justify the increased cost. That is, pick-and-place equipment may only be able to achieve 20-25,000 units per hour (UPH) whereas 100,000 UPH or more is needed for true high speed manufacturing. However, utilizing multiple pick-and-place machines in a line significantly increases the complexity of the manufacturing process and the possibility of error.

Another approach, referred to as a “self-assembly process,” is a method in which multiple chips are first dispersed in a liquid slurry, shaken and assembled into a substrate containing chip receiving recesses. Some current processes are described in U.S. Pat. No. 6,848,162, entitled “Method and Apparatus for High Volume Assembly of Radio Frequency Identification Tags,” issued to Arneson, et al. on Feb. 1, 2005; U.S. Pat. No. 6,566,744, entitled “Integrated Circuit Packages Assembled Utilizing Fluidic Self-Assembly,” issued to Gengel on May 20, 2003; and, U.S. Pat. No. 6,527,964, entitled “Methods and Apparatuses for Improved Flow in Performing Fluidic Self Assembly,” issued to Smith et al. on Mar. 4, 2003. Publications, patents and patent applications are referred to throughout this disclosure. All references cited herein are hereby incorporated by reference.

Accordingly, there is a long-felt, but as yet unsatisfied need in the RFID device manufacturing field to be able to produce RFID devices in high volume, and to assemble them at much higher speed per unit cost than is possible using current manufacturing processes.

### SUMMARY OF THE PREFERRED EMBODIMENTS

The present invention for creating RFID devices provides high yield of transfer and bonding of RFID chips from chip carriers to device matrices with a near infrared (NIR) bonding process. The chips are directly bonded to the strap leads or antenna leads from the chip carriers. In one preferred embodiment, the process includes the steps of selectively removing and transferring of RFID chips to the chip carrier with predetermined pitches; and bonding the chip to strap leads or antenna leads using the NIR bonding process.

In one preferred embodiment, the techniques that are used to implement the present invention include:

1. Selective removal and transfer of chips to a chip carrier where the chips have a pitch that substantially matches the pitch of the strap leads or the antenna leads.

Using the selective chip transfer techniques as described herein, chips can be selectively removed and transferred from a wafer or a chip carrier to another chip carrier to result in a chip carrier with chips spaced at a different pitch. There is no size limitation of chip carrier in these selective chip peeling and transfer processes. UV-reactive adhesive tapes and functional adhesive carriers, as described herein, can be effectively used in these selective transfer processes.

2. Selective removal and transfer of chips to a chip carrier where the chip position is not changed during the peeling and transfer process.

Since there is no tape expansion or extension during the selective chip removal and transfer processes, the original position of each chip is not changed through these removal and transfer processes.

3. Bonding of the chips to the strap leads or the antenna leads through a NIR bonding process:
a. In one preferred embodiment, the strap leads have a pitch that match the pitch of the chips. The chip carrier may be a carrier having an adhesive coated thereon where the adhesive can be detacked by UV light, heating or other conditions.
b. Each strap lead or each antenna lead has a heat curable adhesive dropped onto it.
c. An alignment system is used to put the chip side of the chip carrier onto the strap lead carrier or the antenna lead carrier, after which each chip is contacted with the adhesive on each strap lead or antenna lead.
d. A special plate, such as a piece of glass plate, may be put above the back side of chip carrier, to apply pressure to and thus flatten both the chip carrier and the strap lead or antenna lead carrier. This increases the quality of both the contact of each chip to each strap lead or antenna lead, and the uniform heating of the NIR bonding process, which is a thermal pressing process.
e. The NIR process is used to heat the heat curable adhesive between each chip and each strap lead or antenna lead, and thus solidify the contact between each chip to each strap lead or antenna lead. Then, the chip carrier is removed and the chip bonded strap lead or the chip bonded antenna lead is formed.

The chip can be bonded directly to the strap lead carrier or the antenna lead carrier without limitation on the size of the chip carrier. No other process is needed between the selective removal and transfer process and the chip bonding process.

Other features and advantages of the present invention will become apparent to those skilled in the art from the following detailed description. It is to be understood, however, that the detailed description of the various embodiments and specific examples, while indicating preferred and other embodiments of the present invention, are given by way of illustration and not limitation. Many changes and modifications within the scope of the present invention may be made without departing from the spirit thereof, and the invention includes all such modifications.

### BRIEF DESCRIPTION OF THE DRAWINGS

The invention may be more readily understood by referring to the accompanying drawings in which:

FIG. 1 is a high-level flow diagram of a method for manufacturing a semiconductor device in accordance to a preferred embodiment of the present invention;

FIG. 2 is a side view of a plurality of chips located on a first substrate, with a second substrate being brought into the proximity of the plurality of chips pursuant to one preferred embodiment of the present invention;

FIG. 3 is a side view of the plurality of chips of FIG. 2 located between the first and second substrates with a plurality of masks placed on the substrates pursuant to one preferred embodiment of the present invention;

FIG. 4 is a side view of the structure of FIG. 3 being exposed to an ultraviolet light source pursuant to one preferred embodiment of the present invention;

FIG. 5 is a side view of plurality of chips of FIG. 2 being separated into two separate groups of chips after the plurality of masks have been removed pursuant to one preferred embodiment of the present invention;

FIG. 6 is a side view of an alternate embodiment of a masking of a structure pursuant to one preferred embodiment of the present invention;

FIG. 7 is a side view of the structure of FIG. 6 being separated into two substrates after the plurality of masks have been removed pursuant to one preferred embodiment of the present invention;

FIG. 8 is a side view of a plurality of chips located on a first substrate being attached to a second substrate coated with a functional adhesive;

FIG. 9 is a side view of the plurality of chips of FIG. 8 transferred to the second substrate coated with the functional adhesive;

FIG. 10 is a side view of a second embodiment of a plurality of chips located on a first substrate being attached to a second substrate coated with a functional adhesive;

FIG. 11 is a side view of a third embodiment of a plurality of chips located on a first substrate being attached to a second substrate coated with a functional adhesive;

FIG. 12 is a side view of the plurality of chips located on the second substrate being attached to strap leads;

FIG. 13 is a side view of a structure where a subset of chips from a plurality of chips are selectively transferred and bonded to strap leads;

FIG. 14 is a plan view of a first mask used in the structure of FIG. 13; and

FIG. 15 is a plan view of a second mask used in the structure of FIG. 13.

Like numerals refer to like parts throughout the several views of the drawings.

### DETAILED DESCRIPTION

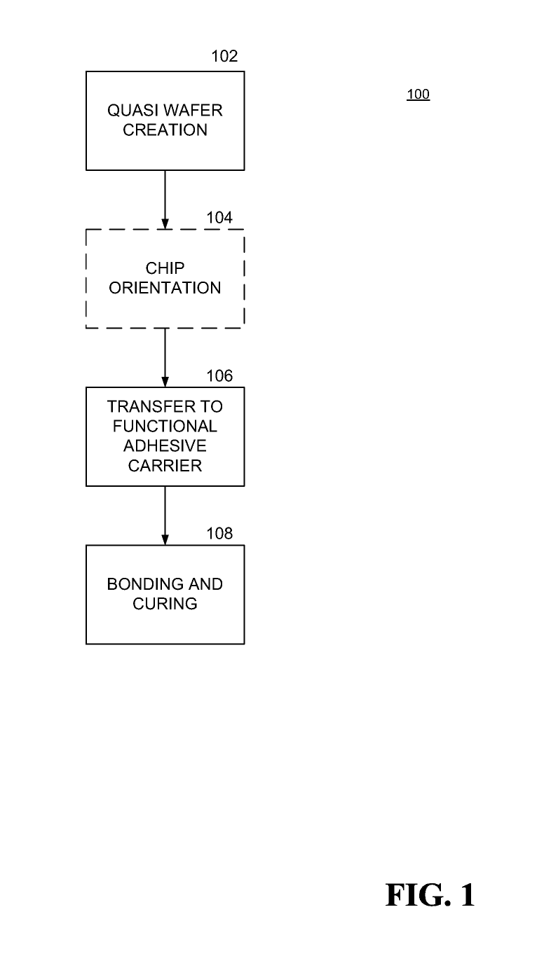

FIG. 1 is a high-level overview of one preferred embodiment of a process 100 for the creation of a chip assembly of the present invention adapted for the manufacturing of RFID devices. In general, process 100 as illustrated involves several different stages, including: a quasi-wafer creation stage 102, during which a plurality of dies (i.e., chips or semiconductor devices) from a wafer is transferred from the wafer to create quasi-wafers, as further defined herein; a chip orientation stage 104, during which the orientation of the chips on the quasi-wafers are adjusted; a chip transfer to functional adhesive carrier stage 106, during which the chips from the quasi-wafers are transferred to a carrier (also referred as a substrate) coated with a functional adhesive such as a temperature sensitive adhesive (TSA); and a bonding and curing stage 108, in which the chips on the functional adhesive carrier are transferred and each attached to respective strap leads on a strap lead carrier having a second adhesive dispensed thereon. During this last step, the chips may simultaneously be bonded to the strap leads and the second adhesive cured. As is further detailed below, portions of the die separation and strap lead attachment process described herein may be optional and the described process may include portions that are not needed for a particular application. Therefore, the following description should be read as illustrating exemplary embodiments of a novel chip separation and strap lead attachment process as practiced in one preferred embodiment of the present invention and should not be taken in a limiting sense.

As used herein, the term “quasi-wafer” refers to a subset of chips transferred from an original wafer, wherein the position of each chip on the quasi-wafer relative to the other chips in the original wafer does not change. In one preferred embodiment, a quasi-wafer is created by removing every other row of chips and then every other column of chips from an original wafer, resulting in at least one quasi-wafer where each chip on the quasi-wafer is without any adjacent chips. In this preferred embodiment, four quasi-wafers may be created from an original wafer. In other preferred embodiments, fewer or more chips may be removed so that strap leads, which are created on a substrate with a pitch matched to the pitch of the chips in the quasi-wafer, may be attached to the chips. Thus, the term quasi-wafer may refer to any subset of chips removed from the original wafer, but where each chip maintains its original position.

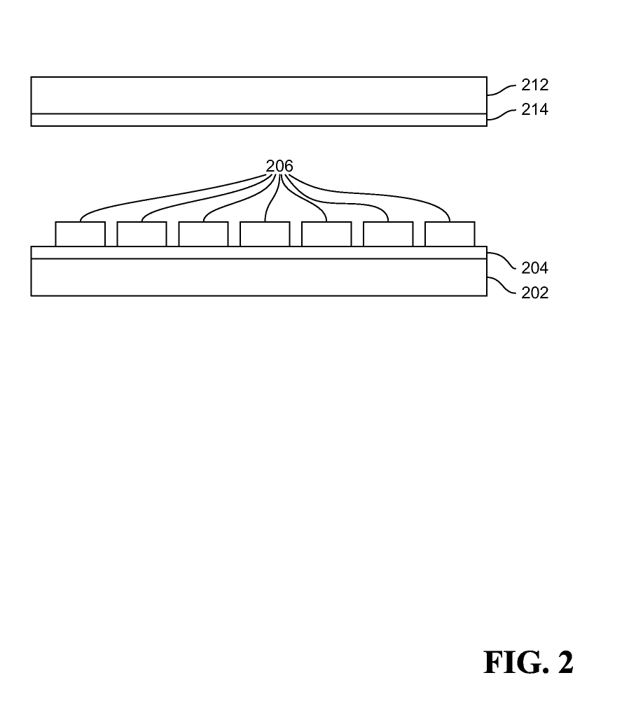

With reference to FIG. 2, process 100, in step 102, begins with the selective transference of a portion of a plurality of chips 206 from a wafer tape 202 to create quasi-wafers. In one preferred embodiment, step 102 is directed to the performance of selective parallel die transfer from a first substrate (such as a diced wafer on a wafer tape) to a second substrate having an adhesive that differs from the adhesive on the first substrate by level of adhesion. In another preferred embodiment, the second surface includes a patterned surface having different adhesion levels. Specifically, step 102 involves the selective transfer of chips from one substrate to another using differences in the levels of adhesion of a predetermined pattern of chips to each substrate. The different levels of adhesion on each substrate can be created using various physical and physical-chemical patterning methods.

In one preferred embodiment, the different levels of adhesion are created using a radiation source, such as an Ultraviolet (UV), Infrared (IR), or Near IR (NIR) light source in conjunction with shadow masks to create a pattern of exposed and covered areas on a carrier (or substrate) coated with an adhesive sensitive to the radiation source. In this embodiment, the adhesiveness in the areas exposed to the radiation source are deactivated (or activated), resulting in lower (or higher) adhesion. Coherent light sources (such as lasers) can also be used as the radiation source without using any masks. In another preferred embodiment, the patterning of the substrates is done by the selective dispensing or printing of adhesives or other materials in order to selectively increase/decrease the adhesion in desired locations. For example, a tape patterned with UV-reactive adhesives may be used to selectively remove any number of chips from a die matrix. In this example, an additional activation or deactivation step may be necessary, which can be achieved by using UV radiation. Other types of radiation such as the aforementioned IR or NIR radiation may be used, based on the specific type of adhesives used.

In one preferred embodiment of the quasi-wafer creation process, the transfer is a two-dimensional to two-dimensional transfer that involves selective chip transfer from one wafer into multiple quasi-wafers in two steps. The first step involves transferring the entire wafer (e.g., plurality of chips 206) to a new support (e.g., tape 202) having an UV-reactive adhesive 204. In one preferred embodiment, a tape having UV-reactive adhesives coated or dispensed thereon, such as the 1027R tape from Ultron System of Moorpark, Calif., as currently available from MINITRON Elektronik GmbH, may be used. It is desirable that the tapes used have a stable, substantially unstretchable substrate such as polyethylene terephthalate (PET). It is also desirable to use frames to mount each tape. The frame may be rigid in shape but can be bent if necessary.

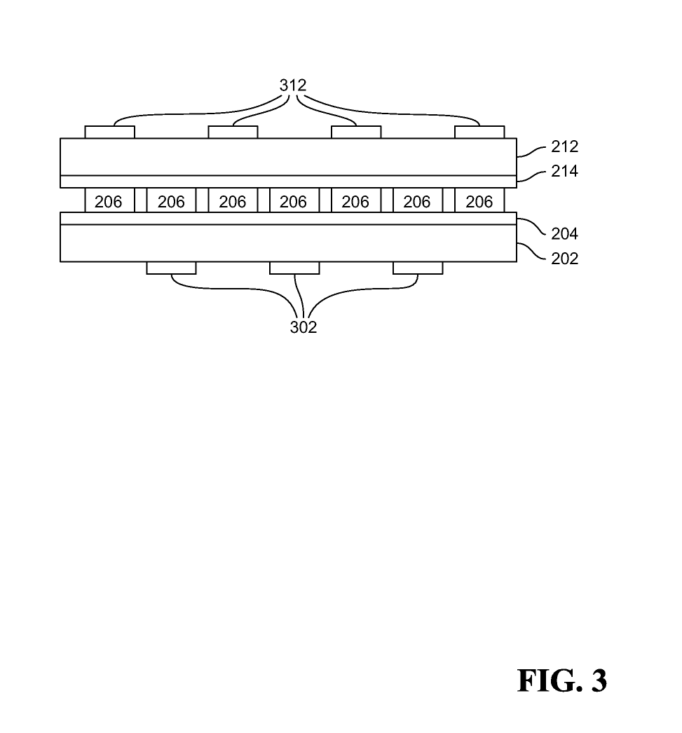

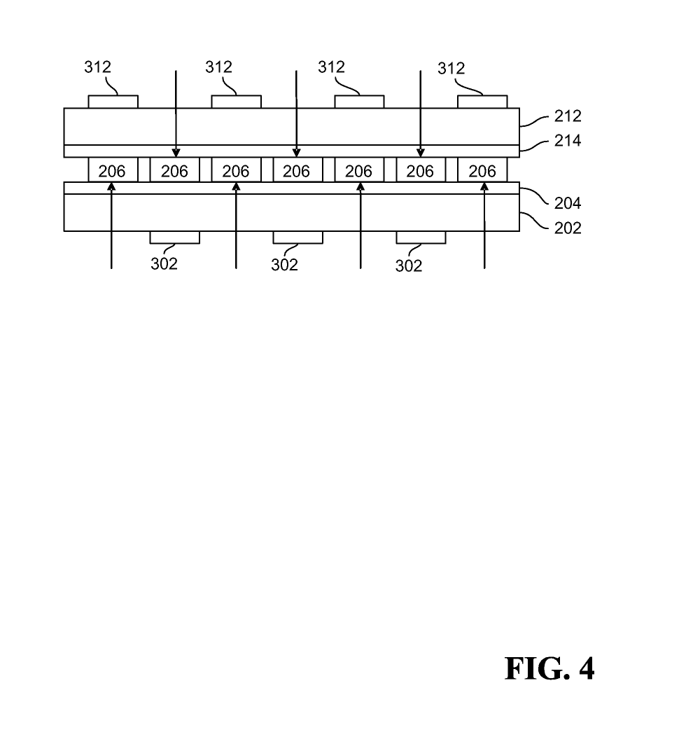

The second step involves the attachment of a second tape having UV-reactive adhesives coated or dispensed thereon to the chips transferred to the first tape. Thus, referencing FIG. 2 and FIG. 3, a second tape 212 also having an UV-reactive adhesive 214 coated or dispensed thereon is attached to the second side of plurality of chips 206, resulting in the plurality of chips 206 being sandwiched between the two supports. Adhesive 204 and 214 may be the same adhesive or they may be entirely different adhesives. In one preferred embodiment, selected rows of chips are then masked from one side using a first plurality of masks 302 and the chips that are not masked are masked from the second side using a second plurality of masks 312. In FIG. 4, exposure to UV radiation results in any unmasked adhesive portions becoming detackified.

In one preferred embodiment, first tape 202 and second tape 212 are then pulled apart in a peel angle in the range of between about 40-50°, with an angle of approximately 45° being preferred, relative to the chip edges, to separate the wafer into alternate rows of chips on each of the supports. When separating the tapes, a peel front is generated. This peel front may impinge on a chip either orthogonally or non-orthogonally. As defined herein, orthogonal refers to the fact that the peel front impinges on an entire first edge of a chip simultaneously. Preferably, the peel angle would be non-orthogonal but would involve symmetrically separating the support tapes. In one preferred embodiment, the non-orthogonal angle would be approximately 45° relative to a first edge of a chip.

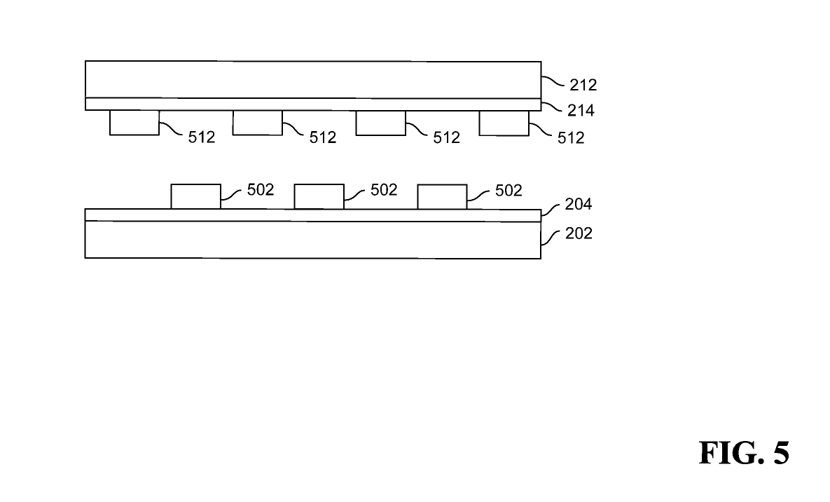

FIG. 5 illustrates the separated chips, where a first portion of chips 502 from plurality of chips 206 remain attached to adhesive 204 on first tape 202; and a second portion of chips 512 from plurality of chips 206 are now attached to adhesive 214 on second tape 212. After separating the two tapes, the chips are separated into two groups. In the example as shown, the space between the chips in one direction is increased by approximately 100% on each tape as every other row of chips has been separated.

Once a first subset of the chips of the original wafer has been created, it is covered with another support, again sandwiching the chips between the supports. The chips are now masked in alternate columns in the same fashion as when masked row-wise. Now after UV irradiation, when first tape 202 and second tape 212 are again pulled apart at an approximate 45° angle, the respective set of chips (first portion of chips 502 and second portion of chips 512), are arranged on the support in a checkerboard or alternating chip/space pattern. Other patterns are possible, such as two chips/two spaces, one chip/two spaces and so on.

In another approach, instead of transferring the complete wafer of chips to a new support, only predetermined portions of plurality of chips 206 are transferred to new supports directly from wafer tape 202. Thus, for example, every other chip in each row and column can be removed.

In one preferred embodiment, adhesion patterned through the use of UV-reactive adhesive is used because: 1) UV detack tape material is readily available; 2) UV methods are optical methods, so it is possible to achieve resolution to a micrometer level (much smaller than the RFID or diode die size); and 3) it is also very easy to design a system to use UV to selectively pattern a surface, such as a scan laser system, a projection system, or such systems that are commonly used for lithography applications.

Other selective transfer methods that may be used in addition to or in place of the adhesion patterning method as described include: vacuum picking; pick-and-place; and freezing. For example, selective picking may be used to achieve a pitch appropriate for strap lead or antenna lead placement. Selective picking may also be used first to increase the space between the chips (e.g., the space between each of the chips can be increased by 100%) and then freeze/peel/free and selective picking/dispensing may then be used to ultimately achieve the pitch appropriate for attaching to strap leads or antenna leads.

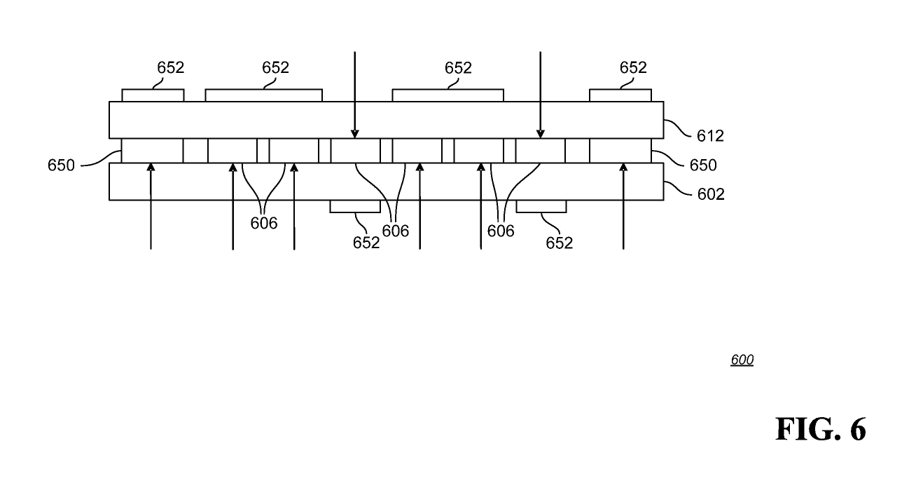

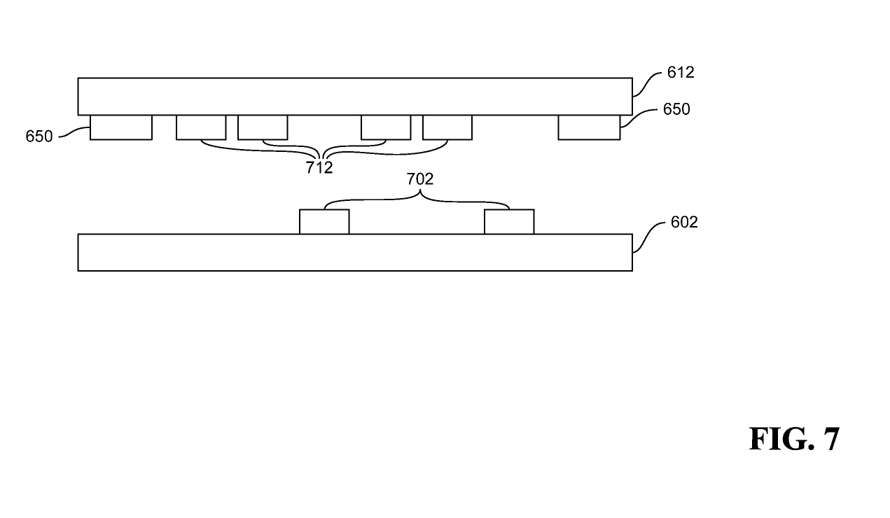

Referring to FIG. 6, a second embodiment of a structure 600 is illustrated where a plurality of chips 606 is sandwiched between a first tape 602 and a second tape 612. In this figure, a different patterning of a subset of chips are being transferred, as defined by all plurality of masks 652. In addition, structure 600 optionally includes a plurality of spacers 650 to prevent first tape 602 and second tape 612 from contacting each other. It should be noted that, to simply the discussion of the subsequent figures, no adhesive layers are shown. FIG. 7 illustrates the separated first tape 602 and second tape 612 having a plurality of chips 702 on first tape 602 and a second plurality of chips 712 on second tape 612.

As discussed above, once the quasi-wafer creation step 102 has been performed, in one preferred embodiment four quasi-wafers will have been created. Two of these quasi-wafers have the chips in a “pads up” orientation and two have the chips in a “pads down” orientation. In one preferred embodiment, an optional orientation step 104 is used to reorient the chips on one set of quasi-wafers to have a desired pad orientation, either contact pads up or contact pads down. Thus, after the execution of chip orientation step 104, all sets of quasi-wafers would have the same pad orientation.

After step 104 has been completed, the chips on the quasi-wafers are being carried on tape and held in place by a functional adhesive (e.g., UV-reactive adhesive in this embodiment). In step 106, the chips are transferred to another substrate and held in place with a temperature-sensitive adhesive (TSA). In one preferred embodiment, the TSA is made by mixing a crystallized additive to a solvent based pressure sensitive adhesive (PSA). The PSA is available, for example, from KIWO, Inc. of Seabrook, Tex. The crystallized additive of turns the PSA into a temperature sensitive adhesive (TSA). Different weights of this additive result in different temperature functionalities of the TSA. In a preferred embodiment, a mixture of 33% of the additive is added to the aforementioned solvent-based PSA.

In one preferred embodiment, the plurality of chips on a quasi-wafer is transferred to a suitable carrier by sandwiching the chips between the UV-reactive carrier and a new carrier coated with TSA. Irradiation with UV light detackifies the UV-reactive adhesive and accomplishes the transfer upon separation of the two carriers. Similar to the separation of the tapes during the quasi-wafer manufacturing process, the separation is preferably performed at a 45° angle relative to the leading edge of the plurality of chips.

As noted above in step 104, half of the quasi-wafers produced have chips held in an orientation that is opposite of what is desired (i.e., either in a pads up or pads down orientation). These chips require one additional transfer in order to obtain quasi-wafers with pads all in the same orientation. This may be done prior to or after the transfer to a TSA coated support. For example, the chips can be transferred to a first TSA coated support, then transferred to a second TSA coated support. In one preferred embodiment, the first and second TSA coated supports have different formulations of TSA to allow the transfer of the chips.

As described herein, functional adhesives such as a TSA or UV-reactive adhesives can be used in the various embodiments. However, it should be noted that other functional adhesives can also be used. The adhesive properties of the functional adhesive may be changed (e.g., increased, reduced or eliminated) by exposure to a predetermined range of stimuli. The stimuli may include UV radiation, heat, light or other stimuli that effect changes in the adhesive properties. The change of the adhesive properties may be temporary or permanent. Further, the change in adhesive properties may be gradual or sudden. For example, the functional adhesive may be a TSA that loses its adhesiveness at higher temperatures, but once the temperature falls below a predetermined temperature, the adhesiveness of the TSA returns.

As discussed, there are many different methods to transfer and bond chips to strap leads and antenna leads. However, the process of transferring and bonding the chips from the die matrix or silicon wafer to strap leads and antenna leads are composed of many different process steps, such as: the expansion of the matrix of silicon wafer, the transfer of the chips from one carrier to another (perhaps multiple times), and using special instruments to pick up and bond the chips to strap leads or antenna leads. An increase in the number of these process steps both limits the production yield and increases the risk of chip contamination.

To reduce the number of steps, it is proposed herein that a process whereby selective chip transferring and NIR bonding steps are used to directly bond chips, contained on a chip carrier, to strap leads or antenna leads. As used herein, the term “strap” refers to an assembly where a chip is already bonded to a strap lead or lead frame, whereas the terms “strap lead” or “lead frame” refers to a chip to antenna connection structure. The bonding process can be performed for a plurality of chips and, thus, a large number of chips can be bonded onto strap leads or antenna leads through just one bonding operation. The chip carrier is, in one preferred embodiment, a carrier that is coated with adhesives. Functional adhesives are used on the substrates supporting the chips during the transferring and bonding of the chips. The advantages of using functional adhesives include the fact that the adhesives can be screen printed or printed with other printing methods and the adhesive printed on the carrier can be recyclably used for many cycles. Use of the reusable adhesives provides many ways to simplify and speed up the chip transfer process.

In one preferred embodiment, functional adhesives are recyclably used for many times in chip transfer and bonding. The chips are transferred from one substrate to the functional adhesive carrier at ambient conditions and then transferred again or bonded from the functional adhesive carrier to another substrate or device at a predetermined temperature, i.e., at a temperature that causes the functional adhesive to release the chips. The utilization of recyclable functional adhesives can simplify the chip transfer process, increase chip transfer and bonding yields, and reduce production costs.

1. Exemplary use of functional adhesives.
a. In one preferred embodiment, functional adhesives are used that have enough adhesion or tackiness to peel away the chips from the UV-detacked adhesive tapes or other kinds of adhesive tapes at room temperature. Thus, the chips are transferred onto the functional adhesive coated carrier.
b. The functional adhesive coated carrier, with the chip thereon, is heated up to a temperature of about 50° C. At around this temperature, the adhesion (tackiness) of the functional adhesive is greatly reduced or eliminated, so the chips can easily be transferred to another substrate, such as onto strap leads or antenna leads.
c. When the functional adhesive coated carrier from which the chips have been peeled away is cooled to room temperature, the functional adhesive regains its adhesion (tackiness), and thus can be used to again peel away or transfer the chips from another UV-detacked adhesive tape or other kinds of adhesive tapes at room temperature.
d. Steps “a-c” can be repeated numerous times.

2. In one preferred embodiment, the functional adhesive is comprised of printable liquid materials and dried as a rubbery adhesive material for a surface. Examples include hot melt or solvent-based adhesives.
a. The functional adhesive can be printed on the carrier substrate with predetermined patterns, such as dots, bar, segments, strips, lines, other geometric patterns, etc.
b. The dried adhesive pattern preferably keeps its original shape. Specifically, the adhesive function and pattern shapes preferably do not change throughout the chip transfer and bonding processes.

3. Examples of applications of the functional adhesive during the chip transfer and bonding process.
a. The functional adhesive can be printed as the chip transfer media on a carrier belt.
b. The carrier belt can be installed and work as the transfer web in a chip transfer and bonding process. In one preferred embodiment, the functional adhesive coated web is moved to a first station, where the adhesive is used to peel the chip away from its original carrier and then the web is moved forward to the next station where the functional adhesive is heated so that the chips are transferred or bonded onto another carrier, or strap lead carrier or antenna lead carrier.
c. The carrier belt can be installed as a side of a rotatable drum. When the drum is rotating, the adhesive belt goes through the first station to peel away the chip from the original carrier. Then the adhesive belt is rotated to the second station where the belt is heated so the chips are transferred from the belt to another carrier, such as a strap lead carrier, antenna lead carrier or web. Selective peeling and transferring of the RFID chips to the carrier then occurs, where the chips are spaced at a pitch that matches the pitch of the strap leads or the antenna leads are transferred.
d. The functional adhesive can be printed on a plate to create a chip transfer plate. The plate can be used to transfer the chips with the same function as described in steps “b” and “c”.

In one preferred embodiment, adhesive dots of approximately 1 mm in diameter are screen printed onto a PET substrate having a thickness of approximately 7 mils by syringe. The adhesive dots are dried at approximately 70° C. for approximately 10 minutes. These adhesive dots are able to peel the chip away from the UV detacked tape at room temperature. The PET substrate with the chips attached by adhesive dots is heated to 60° C., then a tape such as Ultron System No. 1020° R tape, which is a UV detackable adhesive coated on polyvinyl chloride (PVC), is pressed against and contacted with the chips and the PET substrate. The tape is peeled away from the PET substrate, with the chips being transferred onto 1020R tape.

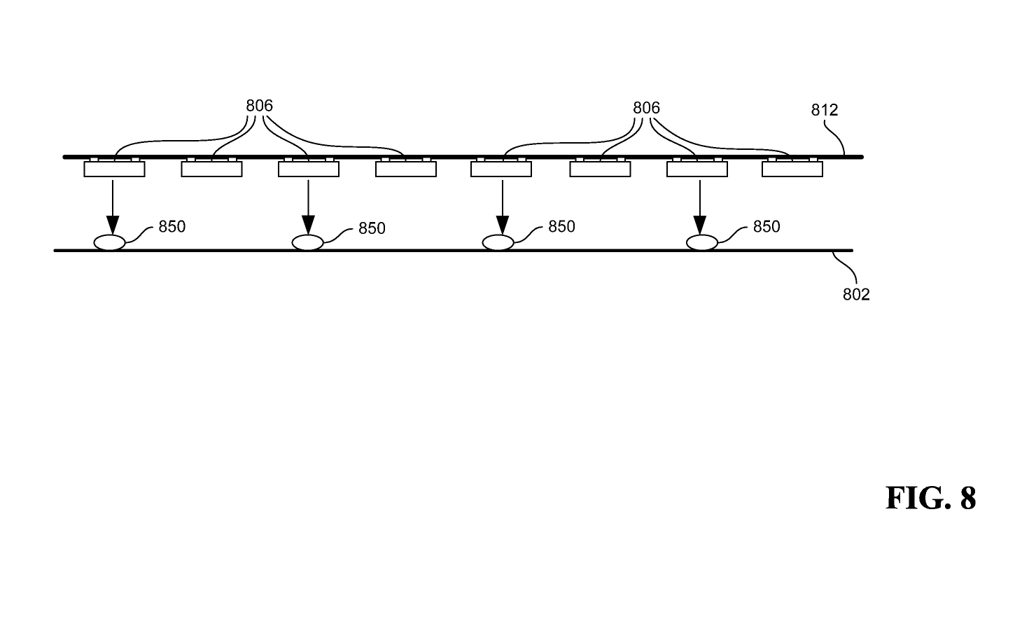

In a first preferred embodiment for transferring chips to a TSA carrier, as illustrated in FIG. 8, the process begins with the printing (by screen or gravure) or dispensing by multi-head high speed dispenser of a functional adhesive 850, i.e., a TSA or a UV detackable adhesive on a roll substrate 802 according to the strap lead or antenna lead layout of chip placement area. In one preferred embodiment, pitches of approximately 4.8 mm in horizontal and approximately 10 mm in vertical directions for the strap leads are used. It is assumed that, in one preferred embodiment, the pitches of the strap leads can be defined as whole number multiples of the pitches of the chips in horizontal and vertical directions.

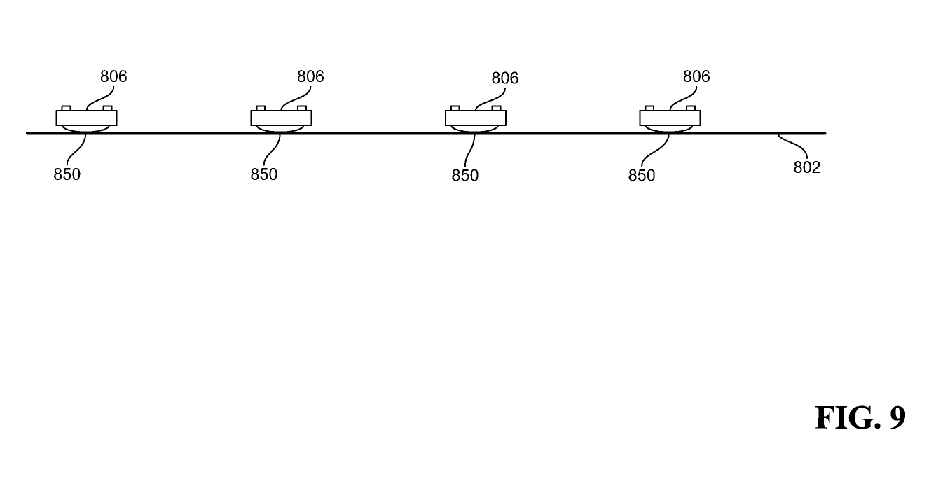

If the adhesive pattern or dot size is smaller than the chip area, a little stretch of the wafer backing tape may be used to separate chips. Thus, there may not be a need to selectively transfer the wafer before this step. An alignment system may then be used to align a wafer tape 812 having a plurality of diced chips 806 (stretched or selectively transferred or in the original form) to the substrate of patterned adhesive. In one preferred embodiment, wafer tape 812 is an UV backing tape that is detackified by UV radiation. In one preferred embodiment, plurality of chips 806 have their pads facing toward wafer tape 812. The plurality of chips 806 is then aligned to adhesive dots 850 or patterns and the gap between the two surfaces (wafer tape 812 and roll substrate 802) are closed to get certain chips to contact the adhesive printed areas. Once the gap between those two surfaces is opened, the chips in contact with the adhesive dots or patterns will separate from the wafer and stay on the adhesive dots. FIG. 9 illustrates a plurality of chips, each mounted to a respective adhesive dot or pattern. Both the wafer and the adhesive printed tape are indexed and aligned again and the here-before described procedure is repeated until all chips are transferred in a rectangular form of, in one preferred embodiment, less than or equal to 8 lanes of chips with a pitch of approximately 10 mm. The chips are separated on each lane by a predetermined pitch (e.g., approximately 4.8 mm). In one preferred embodiment, a rectangular form of chip placement is achieved on the adhesive printed substrate from the wafer circular form.

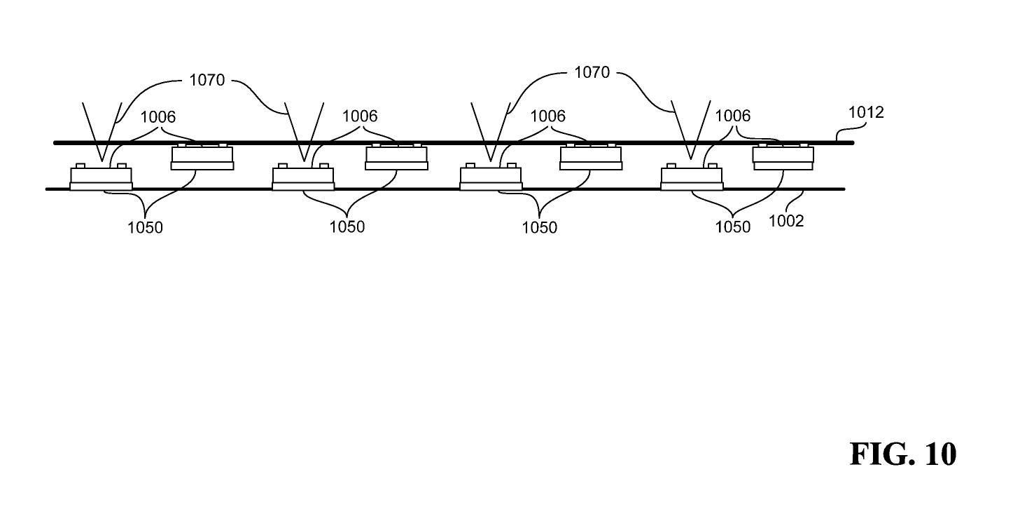

In another preferred embodiment, as illustrated in FIG. 10, instead of printing the carrier tape with adhesive dots, a coating 1050 is placed on the back of each chip 1006 in a wafer tape 1012 (with the backside of each chip facing away from the wafer tape 1012) with the same functional adhesive described above (e.g., a heat-switchable adhesive). In this embodiment the transfer of chips to a carrier tape 1002 may be performed more easily and precisely, but the chips to be transferred must be placed on a lower plane than the chips not to be transferred to avoid having all chips in contact with the carrier tape. This can be achieved by using a sharp edge 1070 to push one or several lines of chips down in contact with carrier tape 1002. In one preferred embodiment, the pitch between each line of chips on the wafer tape 1012 (e.g., the pitch being created by selective transfer) is defined according to the larger, final pitch of the devices to which the chips are to be coupled. The final pitch is a multiple of the smaller distance defined by the chips before the selective transfer.

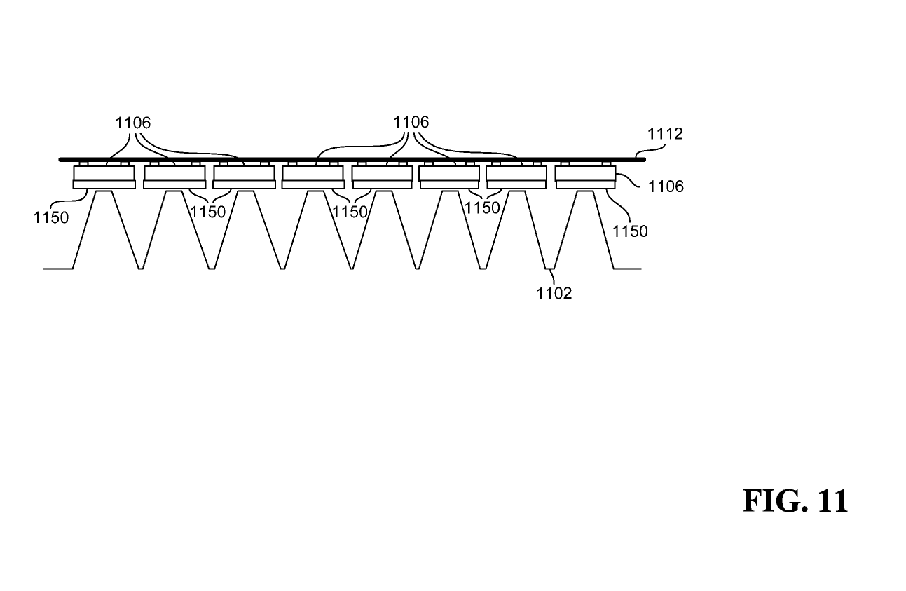

In yet another preferred embodiment, as illustrated in FIG. 11, a carrier tape 1102 having a zigzag shape may be used to contact and peel off a plurality of chips 1106 from a substrate 1112 according to the smaller pitch of strap leads. The plurality of chips, 1106 are coated with adhesives 1150. The zigzag shape may be then extended to produce the second (larger) pitch of the strap leads on the carrier. Carrier tape 1102 may be reusable and designed as a belt.

Once the step of transferring the chips to the TSA carrier has been completed, process 100 continues with step 108.

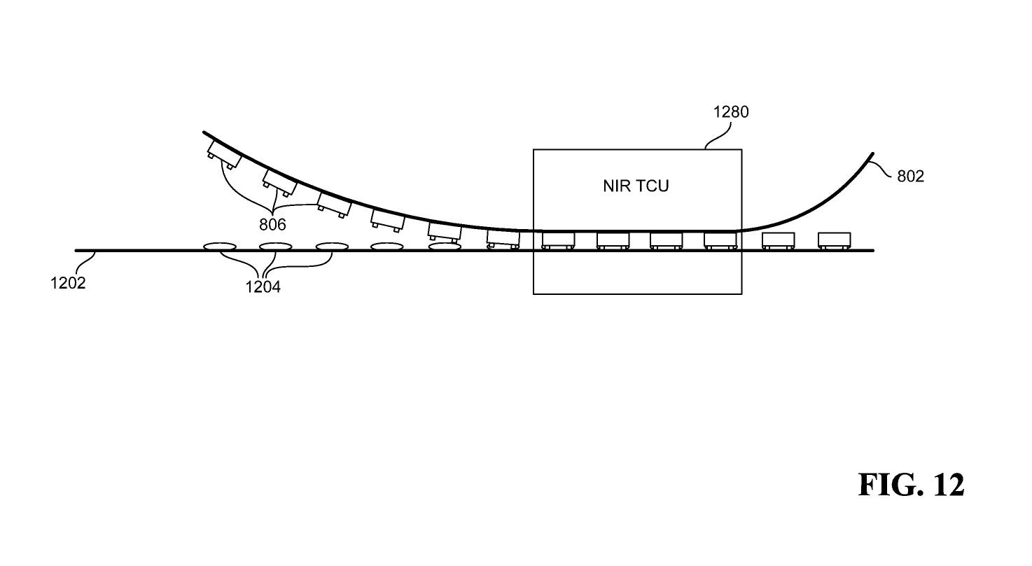

Referring to FIG. 12, a final step 108 of process 100 attaches chips 806 to a final substrate 1202 that contains strap leads and associated electronics. Adhesive dots 850 are not shown in the figure to simplify the illustration. Anisotropic conductive paste (ACP) 1204 is placed on a final substrate 1202 at the position where each chip will reside. Nonanisotropic conductive paste (NCP) may also be used. In one preferred embodiment, carrier 802 is laminated to the final substrate 1202 (e.g., web of strap leads or antenna leads) and bonded using a NIR thermocompression unit 1280. Then, carrier 802 is peeled off.

In one preferred embodiment, NIR thermocompression unit 1280 has a web handling system capable of positioning two webs within a precision of better than +/−30 micrometers (•m). The carrier 802 is laminated to the ACP dispensed final substrate 1202 (e.g., strap lead web) before entering into the NIR thermocompression unit 1280, in which the chips 806 are bonded to the strap leads by the ACP 1204 being cured under pressure. In case the functional adhesive used is a TSA, it is detacked under heat and the carrier substrate (e.g., carrier 802) can be easily removed from the strap lead web (e.g., final substrate 1202) at the exit from the NIR thermocompression unit 1280. In cases where other functional adhesives are used (e.g., UV detackable adhesives), a UV radiation unit may be used inline after the NIR thermocompression unit 1280 to detack the adhesive and peel off the carrier substrate.

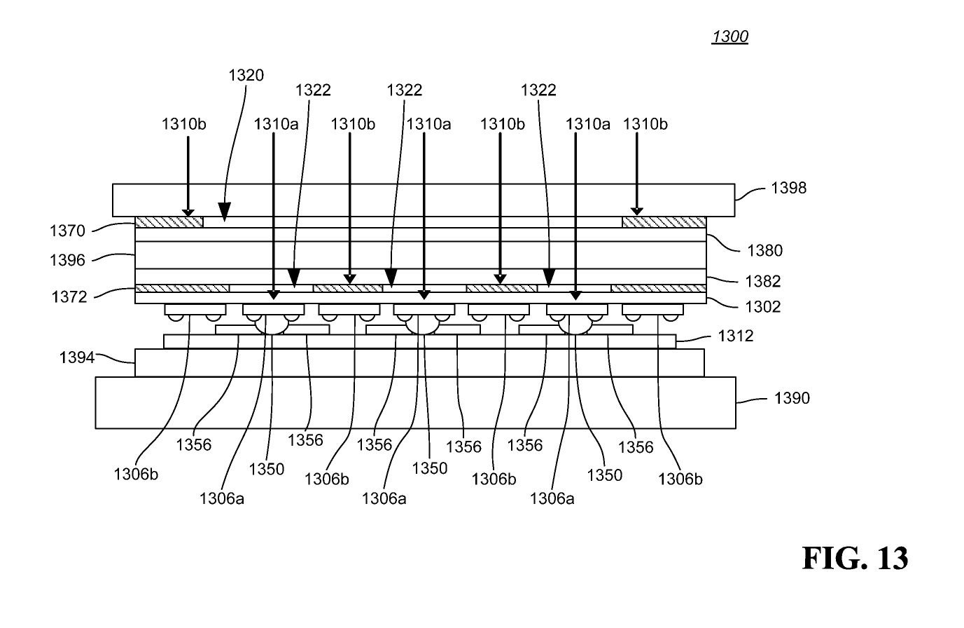

FIG. 13 illustrates a plan view of a structure 1300 where a subset of chips 1306a of a plurality of chips, located on a chip carrier 1302, are selectively transferred and bonded to a plurality of strap leads 1356, located on a strap lead carrier 1312. In one preferred embodiment, the subset of chips 1306a are aligned to the plurality of strap leads 1356 by the alignment of the chip carrier 1302 to the strap lead carrier 1312. The distance between each of the strap leads in the plurality of strap leads 1356 are approximately matched to multiples of the spacing between each of the chips in the plurality of chips. The strap lead carrier 1312 rests on a plate 1394 that is preferably transparent and rigid, which itself rests on a platen 1390. Exemplary materials that may be used for the plate 1394 include glass or quartz. Structure 1300 includes a pair of masks 1370, 1372, which in one preferred embodiment is constructed of aluminum. Sandwiched between pairs of masks 1370, 1372 are a pair of silicon layers 1380, 1382, in between which is a glass plate 1396. A quartz layer 1398 is used to press down on this masking structure to apply pressure to the plurality of chips 1306a to press against a plurality of ACP droplets 1350 dispensed on the plurality of strap leads 1356. Although pressure is also applied to a subset of chips 1306b, they are not transferred as there are no corresponding strap leads on strap lead carrier 1312. The quartz layer 1398 allows a plurality of NIR rays to penetrate it without absorbing a significant amount of the energy of the plurality of NIR rays.

As shown in the figure, a subset of NIR rays 1310a of the plurality of NIR rays is allowed through pair of masks 1370, 1372 to heat up the subset of chips 1306a. Along with the pressure applied, the heat cures the plurality of dispensed ACP droplets 1350. In another preferred embodiment, the plurality of dispensed ACP droplets 1350 are heated and cured by its exposure to the subset of NIR rays 1310a. A subset of NIR rays 1310b are reflected by the pair of masks 1370, 1372 and does not reach the subset of chips 1306b. In one preferred embodiment, both subset of chips 1306a and subset of chips 1306b are affixed to the chip carrier 1302 with a TSA and the heat generated by the subset of NIR rays 1310a reduces the adhesiveness of the TSA under subset of chips 1306a. The reduction of adhesiveness of the TSA facilitates the removal of subset of chips 1306a from chip carrier 1302 when the subset of chips 1306 are bonded to the strap lead carrier 1312.

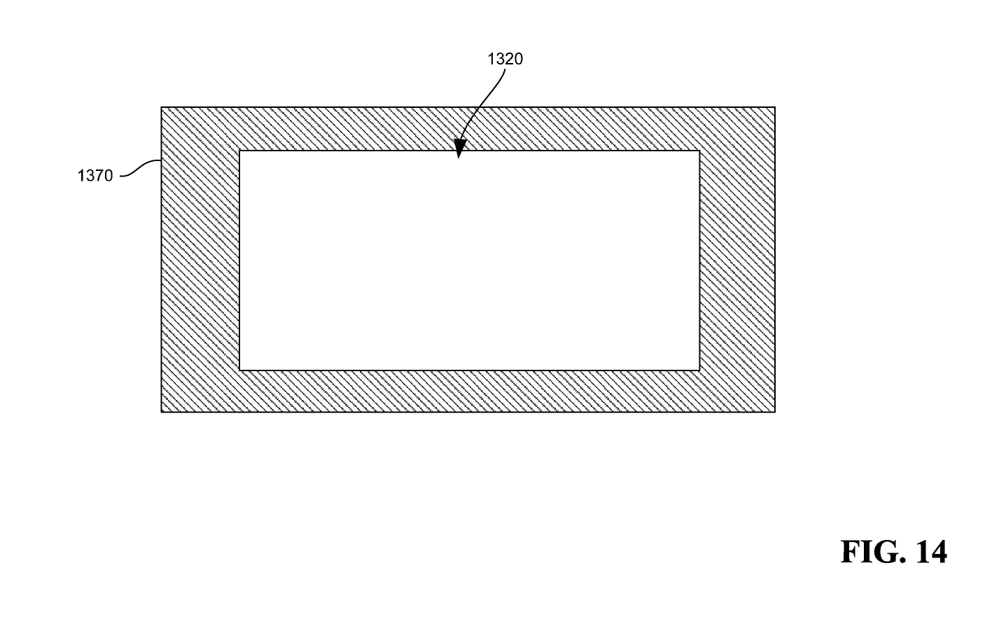

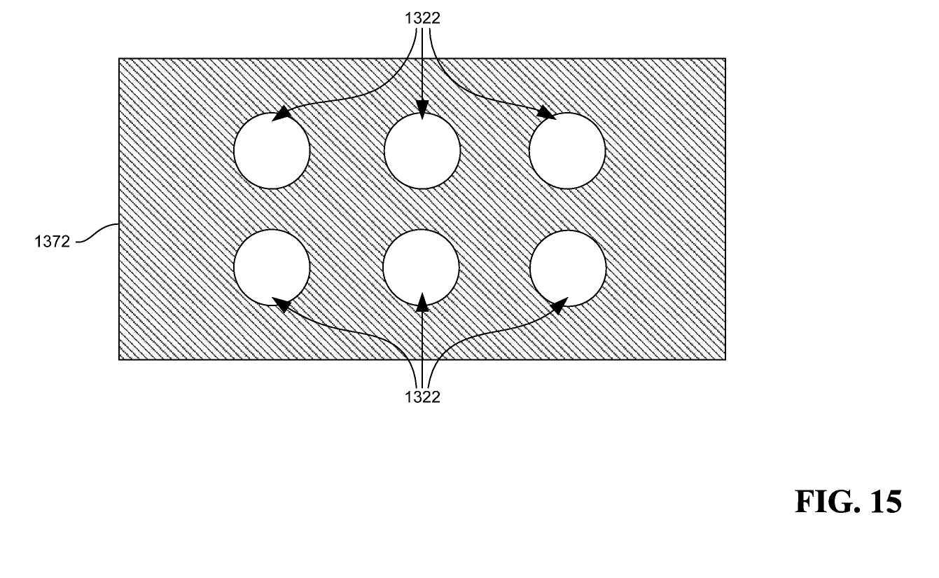

FIG. 14 illustrates a plan view of one preferred embodiment of the mask 1370, where a rectangular opening 1320 is defined therein. FIG. 15 similarly illustrates a plan view of one preferred embodiment of the mask 1372, where a plurality of openings 1322 is defined therein. The plurality of openings 1322 are a patterned set of openings, each opening preferably having a size large enough to allow subset of NIR rays 1310a to reach each chip in the subset of chips 1306a. The plurality of openings 1322 may be arranged in any pattern to expose a predetermined number/arrangement of chips. For example, the plurality of openings may be staggered, or in a zigzag pattern. Further, although the plurality of openings 1322 are illustrated as circular openings, other shapes—whether they are geometric shapes or not—may be used and the specific shape of the plurality of openings 1322 is not critical other than to facilitate (or inhibit, as the case may be) the passage of NIR rays 1310a (or NIR rays 1310b).

The pair of masks 1370, 1372 allows selective transfer and bonding of the plurality of chips because the pair of masks 1370, 1372 is used to selectively allow NIR/IR to reach the chips to be transferred. In one preferred embodiment, pair of masks 1370, 1372 are aluminum and have polished surfaces so that NIR radiation is reflected therefrom and does not heat up. Other reflective materials may also be used, the selection and configuration of which depending on the type of radiation to be reflected. In another preferred embodiment, an insulating material can be used to protect the TSA attaching the chips on the chip carrier from temperature changes. In yet another preferred embodiment, instead of protecting predetermined locations on a chip carrier from being exposed to temperature changes, radiation absorption elements or temperature changing elements (e.g., heated grid) may be used to localize the temperature changes needed to reduce the adhesiveness of the TSA and/or cure the adhesives attaching the chips to the strap leads. Further, targeted coherent light such as lasers may also be used to heat specific locations.

It should be noted that although quasi-wafers have been used to describe certain concepts of chip transfer and attachment contained herein, arrangements of chips other than in quasi-wafers can also be used. For example, in the chip transfer and bonding approach shown and described with respect to FIG. 13, the arrangement of chips from the original wafer may be used with the introduction of sufficient space between each of the chips. Thus, the necessity of the step of creating a quasi-wafer may be eliminated.

The embodiments described above are exemplary embodiments of the present invention. Those skilled in the art may now make numerous uses of, and departures from, the above-described embodiments without departing from the inventive concepts disclosed herein. Accordingly, the present invention is to be defined solely by the scope of the following claims.

What is claimed is:

1. A method for creating a plurality of semiconductor assemblies comprising the steps of:
creating a plurality of quasi-wafers, each quasi-wafer comprising a plurality of semiconductor devices;
transferring the plurality of semiconductor devices on each quasi-wafer onto a carrier having a functional adhesive; and
bonding the plurality of semiconductor devices to a plurality of contacts on a substrate.

2. The method of claim 1, wherein the functional adhesive comprises a radiation-reactive adhesive.

3. The method of claim 1, wherein the functional adhesive is a temperature-reactive adhesive.

4. The method of claim 1, further comprising orienting the plurality of semiconductor devices before bonding the plurality of semiconductor devices to the plurality of contacts on the substrate.

5. The method of claim 1, wherein creating the plurality of quasi-wafers comprises:
providing a semiconductor wafer contained on a first substrate; and
overlaying a second substrate onto the semiconductor wafer, the second substrate having a pattern of adhesive portions to transfer a selected portion of the semiconductor wafer when the second substrate is separated from the first substrate.

6. The method of claim 5, wherein the adhesive portions comprises a radiation-reactive adhesive.

7. The method of claim 5, wherein the pattern of adhesive portions is formed by masking.

8. The method of claim 5, wherein the adhesive portions comprises a temperature-reactive adhesive.

9. An intermediate transfer assembly, comprising;
a first substrate having a first adhesive pattern disposed thereon;
a second substrate having a second adhesive pattern disposed thereon; and
a plurality of chips, disposed between the first substrate and the second substrate, each chip having first and second opposed surfaces, wherein the first surface of each chip is in contact with the first adhesive pattern and the second surface of at least one of the plurality of chips is in contact with the second adhesive pattern.

10. The intermediate transfer assembly of claim 9, wherein the first adhesive pattern and the second adhesive pattern have different levels of adhesion.

11. The intermediate transfer assembly of claim 9, wherein the first adhesive pattern is created after the first surface of each chip has been placed into contact therewith.

12. The intermediate transfer assembly of claim 11, wherein the second adhesive pattern is created after the second surface of the at least one of the plurality of chips has been placed into contact therewith.

13. The intermediate transfer assembly of claim 9, wherein the first adhesive pattern comprises a functional adhesive.

14. The intermediate transfer assembly of claim 13, wherein the functional adhesive comprises a radiation-reactive adhesive.

15. The intermediate transfer assembly of claim 13, wherein the functional adhesive comprises a temperature-reactive adhesive.

16. The intermediate transfer assembly of claim 9, wherein the first adhesive pattern is printed on the first substrate.

17. The intermediate transfer assembly of claim 15, wherein the second adhesive pattern is printed on the second substrate.

18. A method for assembling a semiconductor device comprising the steps of:
providing a first substrate having a plurality of chip attachment locations disposed thereon;
providing an adhesive element on each of the plurality chip attachment locations on the first substrate;
providing a second substrate having a plurality of chips disposed thereon, the plurality of chips attached to the second substrate using an adhesive;
bringing the second substrate in proximity to the first substrate such that at least one of the plurality of chips is in contact with one of the adhesive elements;
reducing the adhesiveness of the adhesive at the location of the at least one of the plurality of chips in contact with one of the adhesive elements; and
curing the adhesive element in contact with the at least one of the plurality of chips.

19. The method of claim 18, further comprising moving the first substrate away from the second substrate, wherein the at least one of the plurality of chips remains bonded to the first substrate after the removal of the second substrate.

20. The method of claim 18, wherein the adhesive on the second substrate is a functional adhesive.

21. The method of claim 20, wherein the functional adhesive is a radiation-reactive adhesive.

22. The method of claim 20, wherein the functional adhesive is a temperature-reactive adhesive.

23. The method of claim 18, wherein reducing the adhesiveness of the adhesive at the location of the at least one of the plurality of chips in contact with one of the adhesive elements comprises providing a mask over the second substrate, wherein the mask includes an opening at the location of the at least one of the plurality of chips in contact with one of the adhesive elements.

24. The method of claim 23, further comprising pressing the mask, the second substrate and the first substrate against each other.

25. The method of claim 23, further comprising exposing the mask to a source of radiation to reduce the adhesiveness of the adhesive on the second substrate at the opening of the mask.

26. The method of claim 23, further comprising exposing the mask to a source of heat to reduce the adhesiveness of the adhesive on the second substrate at the opening of the mask.

27. The method of claim 23, further comprising pressing the mask, the second substrate and the first substrate against each other such that pressure is applied to the at least one of the plurality of chips, the adhesive element, and at least one of the plurality of chip attachment locations.

28. A structure comprising:
a first substrate having a plurality of chip attachment locations disposed thereon;
an adhesive element on each of the plurality chip attachment locations on the first substrate;
a second substrate having a plurality of chips disposed thereon, the plurality of chips attached to the second substrate using an adhesive;
wherein the second substrate is in proximity to the first substrate such that at least one of the plurality of chips is in contact with the adhesive element;
a mask covering the second substrate, wherein the mask includes an opening at the location of the at least one of the plurality of chips in contact with the adhesive element.

29. The structure of claim 28, wherein the adhesive is a functional adhesive.

30. The structure of claim 29, wherein the functional adhesive is a temperature-reactive adhesive.

31. The structure of claim 29, wherein the functional adhesive is a radiation-reactive adhesive.

32. The structure of claim 29, wherein the mask comprises a plurality of openings, and the opening at the location of the at least one of the plurality of chips is one of the plurality of openings in the mask.
